(19) United States
(12) Patent Application Publication
(10) Pub. No.: US 2026/0060146 A1
(43) Pub. Date: Feb. 26, 2026

(54) SEMICONDUCTOR PACKAGE AND METHOD OF MANUFACTURING SEMICONDUCTOR PACKAGE

(71) Applicant: Samsung Electronics Co., Ltd., Suwon-si (KR)

(72) Inventor: Injae LEE, Suwon-si (KR)

(73) Assignee: Samsung Electronics Co., Ltd., Suwon-si (KR)

(21) Appl. No.: 19/304,932

(22) Filed: Aug. 20, 2025

(30) Foreign Application Priority Data
Aug. 21, 2024 (KR) 10-2024-0112340

(51) Int. Cl. H01L 23/00; H01L 23/31; H01L 25/065; H01L 25/18; H10B 80/00; H10D 80/30

(52) U.S. Cl. CPC H01L 24/32; H01L 24/16; H01L 24/26; H01L 24/27; H01L 24/73; H01L 25/0657; H01L 25/18; H01L 23/3128; H01L 24/48; H01L 2224/16225; H01L 2224/26175; H01L 2224/27001; H01L 2224/27515; H01L 2224/32054; H01L 2224/32058; H01L 2224/32059; H01L 2224/3207; H01L 2224/32145; H01L 2224/32225; H01L 2224/48105; H01L 2224/48147; H01L 2224/48149; H01L 2224/48229; H01L 2224/73204; H01L 2224/73215; H01L 2224/73265; H01L 2225/06506; H01L 2225/0651; H01L 2225/06524; H01L 2225/06562; H01L 2924/35; H10B 80/00; H10D 80/30

(57) ABSTRACT

A semiconductor package includes a package substrate including an upper pad on an upper surface of the package substrate, a first chip structure including a plurality of first chips offset-stacked in a first direction, a controller chip on the package substrate and apart from the first chip structure in a horizontal direction, a chip connection bump between the package substrate and the controller chip, and an underfill material layer covering the chip connection bump, wherein a side surface of the underfill material layer is perpendicular to the package substrate.

### CROSS-REFERENCE TO RELATED APPLICATION

This application is based on and claims priority under 35 U.S.C. § 119 to Korean Patent Application No. 10-2024-0112340, filed on Aug. 21, 2024, in the Korean Intellectual Property Office, the disclosure of which is incorporated by reference herein in its entirety.

### BACKGROUND

The inventive concepts relate to semiconductor packages and methods of manufacturing semiconductor packages, and more particularly, to semiconductor packages including semiconductor chips mounted in a flip-chip manner, and methods of manufacturing such semiconductor packages.

Recently, the demand for portable devices has been rapidly increased in the electronic product market, and accordingly, there is continuous demand for miniaturization and weight reduction of electronic components provided in electronic products. For miniaturization and weight reduction of electronic components, semiconductor packages mounted thereon have been required to process large quantities of data while having increasingly smaller volumes.

In this case, in semiconductor packages including semiconductor chips mounted in a flip-chip manner, research has been conducted to reduce the size of the semiconductor package by minimizing or reducing the space occupied by an underfill material layer.

### SUMMARY

The inventive concepts provide semiconductor packages with a reduced size and methods of manufacturing the semiconductor packages.

Also, the problems to be solved by the inventive concepts are not limited to the above problems, and other problems may be clearly understood by those of ordinary skill in the art from the following description.

In order to achieve the technical objects, the inventive concepts may provide at least the following semiconductor packages.

According to some aspects of the inventive concepts, there is provided a semiconductor package including a package substrate including an upper pad on an upper surface of the package substrate, a first chip structure including a plurality of first chips offset-stacked in a first direction, a controller chip on the package substrate and apart from the first chip structure in a horizontal direction, a chip connection bump between the package substrate and the controller chip, and an underfill material layer covering the chip connection bump, wherein a side surface of the underfill material layer is perpendicular to the package substrate.

According to other aspects of the inventive concepts, there is provided a semiconductor package including a package substrate including an upper pad on an upper surface of the package substrate, a first chip structure including a plurality of first chips offset-stacked in a first direction, a controller chip on the package substrate and apart from the first chip structure in a horizontal direction, a second chip structure on the package substrate and apart from the first chip structure in the horizontal direction with the controller chip between the first chip structure and the second chip structure and including a plurality of second chips offset-stacked, a chip connection bump between the package substrate and the controller chip, and an underfill material layer configured to cover the chip connection bump, wherein a side surface of the underfill material layer is perpendicular to the package substrate, and a protrusion protruding upward in a vertical direction is on an upper surface of the underfill material layer.

In order to achieve the technical objects, the inventive concepts provide the following semiconductor package manufacturing methods.

According to other aspects of the inventive concepts, there is provided a method of manufacturing a semiconductor package, the method including attaching a masking tape onto a package substrate including an upper pad so as to surround a certain area of the package substrate, arranging a controller chip including a chip connection bump in an area surrounded by the masking tape, providing an underfill material layer having viscosity between the controller chip and the package substrate, curing the underfill material layer after flow of the underfill material layer is stopped by the masking tape, removing the masking tape from an upper surface of the package substrate, and mounting a first chip structure and a second chip structure on the upper surface of the package substrate so as to be spaced apart from the controller chip, wherein the first chip structure includes a plurality of first chips that are offset-stacked, and the second chip structure includes a plurality of second chips that are offset-stacked.

### BRIEF DESCRIPTION OF THE DRAWINGS

Example embodiments will be more clearly understood from the following detailed description taken in conjunction with the accompanying drawings in which:

FIG. 1 is a plan view schematically illustrating a semiconductor package according to some example embodiments;

FIG. 2 is a cross-sectional view taken along line A1-A1′ of FIG. 1;

FIG. 3 is an enlarged view of region AA of FIG. 2;

FIG. 4 is a plan view schematically illustrating a semiconductor package according to some example embodiments;

FIG. 5 is a cross-sectional view taken along line B1-B1′ of FIG. 4;

FIG. 6 is an enlarged view of region BB of FIG. 5;

FIGS. 7A to 11B are cross-sectional views for describing a method of manufacturing the semiconductor package of FIG. 1; and

FIGS. 12A to 16B are cross-sectional views for describing a method of manufacturing the semiconductor package of FIG. 2.

### DETAILED DESCRIPTION OF THE EMBODIMENTS

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element, value, and/or property is referred to as being the same as another element, value, and/or property, it should be understood that an element, value, and/or property is the same as another element, value, and/or property within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, some example embodiments will be described in detail with reference to the accompanying drawings. Herein, like reference numerals will denote like elements, and redundant descriptions thereof will be omitted for conciseness.

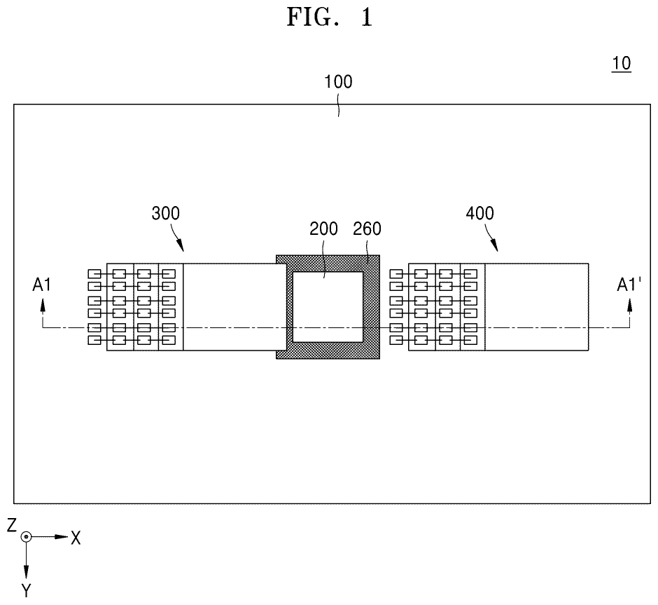

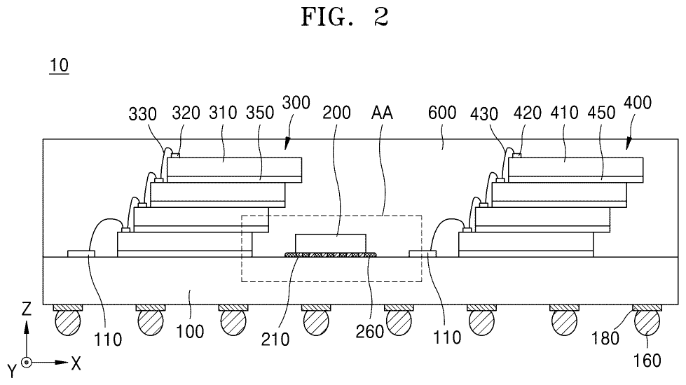

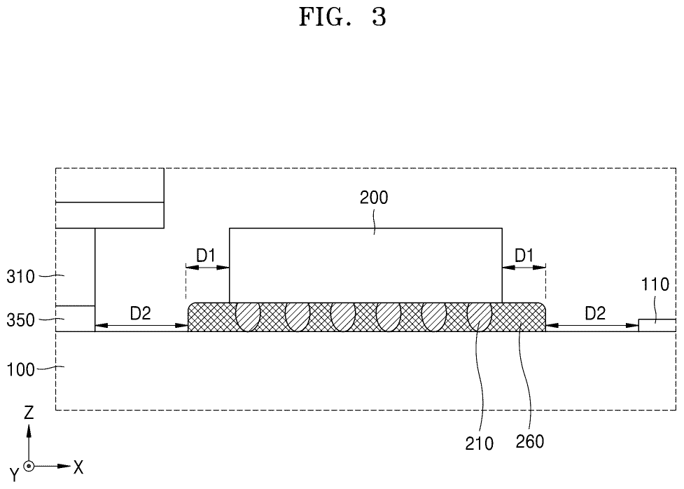

FIG. 1 is a plan view schematically illustrating a semiconductor package according to some example embodiments. FIG. 2 is a cross-sectional view taken along line A1-A1′ of FIG. 1. FIG. 3 is an enlarged view of region AA of FIG. 2. Also, in FIG. 1, illustration of a molding member 600 is omitted for convenience of description.

Referring to FIGS. 1 to 3, a semiconductor package 10 may include a package substrate 100, a controller chip 200, an underfill material layer 260, a first chip structure 300, a second chip structure 400, and a molding member 600. The package substrate 100 may be located under the controller chip 200, the first chip structure 300, and the second chip structure 400 and may be electrically connected to each of the controller chip 200, the first chip structure 300, and the second chip structure 400. The package substrate 100 may include an upper surface and a lower surface that are opposite to each other, and at least one of the upper surface and the lower surface may be a plane.

In the following drawings, a direction parallel to the upper surface of the package substrate 100 may be understood as an X-axis direction and a Y-axis direction, and the X-axis direction and the Y-axis direction may be understood as directions that are perpendicular to each other. A direction perpendicular to the upper surface or the lower surface of the package substrate 100 may be understood as a Z-axis direction, and the Z-axis direction may represent a direction perpendicular to the X-axis direction and the Y-axis direction. Also, in the following drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

The package substrate 100 may include an interconnection insulating layer and an interconnection pattern. The interconnection insulating layer may be provided as a plurality of layers stacked in one direction, and the interconnection pattern may be formed to pass through the interconnection insulating layer from the upper surface to the lower surface of the package substrate 100. Here, the interconnection pattern may function as an electrical connection path that passes through the upper surface and the lower surface of the package substrate 100. According to some example embodiments, the package substrate 100 may include a printed circuit board (PCB). In this case, the interconnection pattern of the package substrate 100 may include copper, nickel, stainless steel, or beryllium copper, and the interconnection insulating layer may include at least one material selected from among phenol resin, epoxy resin, and polyimide. The interconnection insulating layer may include, for example, at least one material selected from among Flame Retardant 4 (FR-4), tetrafunctional epoxy, polyphenylene ether, epoxy/polyphenylene oxide, bismaleimide triazine (BT), thermount, cyanate ester, polyimide, and liquid crystal polymer.

In some example embodiments, the package substrate 100 may include a substrate formed by a redistribution process. In this case, the package substrate 100 may include therein a redistribution pattern and a redistribution insulating layer covering the redistribution pattern. The redistribution pattern may include a metal or a metal alloy such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and/or ruthenium (Ru); however, the inventive concepts are not limited thereto, and in some example embodiments, the redistribution pattern may be formed by stacking a metal or a metal alloy on a seed layer including copper, titanium, titanium nitride, and/or titanium tungsten. The redistribution insulating layer may be formed from a photo imageable dielectric (PID) or a photosensitive polyimide (PSPI).

An upper pad 110 may be located on the upper surface of the package substrate 100. The upper pad 110 may be provided as a plurality of upper pads 110 on the upper surface of the package substrate 100. The upper pad 110 may be connected to a connection terminal such as a wire or a solder ball to electrically connect the package substrate 100 to the first chip structure 300, the package substrate 100 to the second chip structure 400, and the package substrate 100 to the controller chip 200.

An external connection terminal 160 may be located on the lower surface of the package substrate 100 and may be electrically connected to the package substrate 100 through a lower pad 180 formed on the lower surface of the package substrate 100. Particularly, the external connection terminal 160 may be electrically connected to lines formed in the package substrate 100 through the lower pad 180 attached to the lower surface of the package substrate 100. Because the external connection terminal 160 is located under the package substrate 100, the upper surface of the external connection terminal 160 may physically contact the lower pad 180 attached to the lower surface of the package substrate 100. The external connection terminal 160 may be electrically connected to an external device such as a motherboard or a PCB. Because the external connection terminal 160 is arranged between the external device and the package substrate 100, the lower surface of the external connection terminal 160 may be physically connected to the external device.

The external connection terminal 160 may be formed as a solder ball. However, according to some example embodiments, the external connection terminal 160 may have a structure including a pillar and solder. The external connection terminal 160 may include at least one of copper (Cu), silver (Ag), gold (Au), and/or tin (Sb).

The first chip structure 300 may be arranged over the package substrate 100. The first chip structure 300 may include a first chip 310, a first adhesive layer 350, a first chip pad 320, and a first wire 330. The first chip structure 300 may have a structure in which a plurality of first chips 310 are offset-stacked in a first direction. In other words, the first chip structure 300 may have a structure in which a plurality of first chips 310 are stacked in a cascade type, that is, a stair type, in the first direction. According to some example embodiments, the plurality of first chips 310 may be offset-stacked in a direction-X intersecting a first horizontal direction X, or in a direction parallel to a second horizontal direction Y, or in a direction-Y intersecting the second horizontal direction Y. Herein, the first chip structure 300 is illustrated as including four first chips 310; however, the inventive concepts are not limited thereto and the first chip structure 300 may include one or more first chips 310.

The plurality of first chips 310 may be stacked over the package substrate 100 in a stack shape through the first adhesive layer 350. The first adhesive layer 350 may be located between the first chip 310 and the package substrate 100 and between the first chips 310. The first adhesive layer 350 may be configured to attach the package substrate 100 and the first chip 310 located at the lowermost end thereof and may be configured to attach the first chips 310 that are sequentially stacked. According to some example embodiments, the first adhesive layer 350 may include a film having adhesive properties on its own. For example, the first adhesive layer 350 may include a double-sided adhesive film. According to some example embodiments, the first adhesive layer 350 may include a tape-shaped material layer, a liquid coating curable material layer, or a combination thereof. Also, the first adhesive layer 350 may include a thermal setting structure, a thermal plastic, a UV cure material, or any combination thereof. The first adhesive layer 350 may be referred to as a die attach film (DAF) or a non-conductive film (NCF).

As the first chip structure 300 is stacked in a stair type in the first direction, a portion of the upper surface of each of the first chips 310 may be exposed. That is, a portion of the upper surface of each of the first chips 310 may not be covered by the first chip 310 that is offset-stacked directly thereover. When the first chips 310 are stacked in the first direction, a portion of the upper surface of each of the first chips 310 in a second direction, e.g., a portion of the upper surface of each of the second chips 410 at an end of the second chips 410 corresponding to the second direction, which is opposite to and intersects the first direction, may be exposed upward.

The first chip pad 320 may be arranged on the upper surface of each of the first chips 310. According to some example embodiments, the first chip pad 320 may be arranged over an area where a portion of the upper surface of the first chip 310 is exposed upward. That is, the first chip pad 320 may be arranged at a second-direction end on the upper surface of the first chip 310. According to some example embodiments, the first chip pad 320 may be provided as a plurality of first chip pads 320, and the plurality of first chip pads 320 may be provided in an area exposed upward on the upper surface of each of the first chips 310. According to some example embodiments, the first chip pads 320 may be arranged in parallel in the second horizontal direction Y on the upper surface of the first chip 310.

The first wire 330 may be formed on one side of the first chip structure 300. According to some example embodiments, the first wire 330 may be formed on the side where the first chip pad 320 is arranged. That is, when the first chip structure 300 is stacked in the first direction, the first wire 330 may be arranged on the second-direction side that is opposite to and intersects the first direction. In other words, the first wire 330 may be arranged on the upper-surface side that is exposed upward from the first chip 310.

The first wire 330 may be provided as a plurality of first wires 330, and the plurality of first wires 330 may electrically connect the first chip pads 320 having different levels in a vertical direction Z. That is, the plurality of first wires 330 may connect adjacent first chips 310 to each other. Also, the plurality of first wires 330 may be arranged in the second horizontal direction Y to electrically connect the first chip pads 320 having different levels in the vertical direction Z. The first wire 330 may include gold (Au), aluminum (Al), or copper (Cu); however, the inventive concepts are not limited thereto.

The first chip 310 included in the first chip structure 300 may include a semiconductor chip. According to some example embodiments, the first chip 310 may include a memory chip. The memory chip may include, for example, a volatile memory chip such as Dynamic Random Access Memory (DRAM) or Static Random Access Memory (SRAM), or a nonvolatile memory chip such as Phase-change Random Access Memory (PRAM), Magnetoresistive Random Access Memory (MRAM), Ferroelectric Random Access Memory (FeRAM), or Resistive Random Access Memory (RRAM). Also, according to some example embodiments, the memory chip may include a wire bonding memory package or a high-bandwidth memory (HBM) package in which a plurality of memory chips are stacked in the vertical direction Z.

The second chip structure 400 may be arranged over the package substrate 100 and apart from the first chip structure 300 in the horizontal direction (X or Y). The second chip structure 400 may include a second chip 410, a second adhesive layer 450, a second chip pad 420, and a second wire 430. The second chip structure 400 may have a structure in which a plurality of second chips 410 are offset-stacked in the first direction. In other words, the second chip structure 400 may have a structure in which a plurality of second chips 410 are stacked in a cascade type, that is, a stair type, in the first direction. According to some example embodiments, the first direction may be the same direction as the first horizontal direction X. According to some example embodiments, the plurality of second chips 410 may be offset-stacked in the direction-X (an inverse X direction, e.g., a direction extending parallel to the X direction but in an opposite direction) intersecting the first horizontal direction X, or in the direction parallel to the second horizontal direction Y, or in the direction-Y (an inverse Y direction, e.g., a direction extending parallel to the Y direction but in an opposite direction) intersecting the second horizontal direction Y. Herein, the second chip structure 400 is illustrated as including four second chips 410; however, the inventive concepts are not limited thereto and the second chip structure 400 may include one or more second chips 410.

According to some example embodiments, the first chips 310 of the first chip structure 300 and the second chips 410 of the second chip structure 400 may be offset-stacked in the same direction. However, the inventive concepts are not limited thereto, and the first chips 310 of the first chip structure 300 and the second chips 410 of the second chip structure 400 may be offset-stacked in opposite directions. For example, when a side on which wires are formed in each of the first chip structure 300 and the second chip structure 400 is defined as a first surface and a surface opposite to the first surface in the first horizontal direction X is defined as a second surface, when the chips included in the first chip structure 300 and the second chip structure 400 are equally offset-stacked in the first direction, the second surface of the first chip structure 300 and the first surface of the second chip structure 400 may be arranged to face each other as illustrated in FIG. 2. Also, although not illustrated, when the chips included in the first chip structure 300 and the second chip structure 400 are equally offset-stacked in the second direction, the first surface of the first chip structure 300 and the second surface of the second chip structure 400 may be arranged to face each other.

On the other hand, when the first chips 310 of the first chip structure 300 and the second chips 410 of the second chip structure 400 are offset-stacked in opposite directions, that is, when the first chips 310 are offset-stacked in the first direction and the second chips 410 are offset-stacked in the second direction, the second surface of the first chip structure 300 and the second surface of the second chip structure 400 may be arranged to face each other. Also, when the first chips 310 are offset-stacked in the second direction and the second chips 410 are offset-stacked in the first direction, the first surface of the first chip structure 300 and the first surface of the second chip structure 400 may be arranged to face each other. Ultimately, the arrangement direction of the first chip structure 300 and the second chip structure 400 may not be limited to one direction.

The plurality of second chips 410 may be stacked over the package substrate 100 in a stack shape through the second adhesive layer 450. The second adhesive layer 450 may be located between the second chip 410 and the package substrate 100 and between the second chips 410. The second adhesive layer 450 may be configured to attach the package substrate 100 and the second chip 410 located at the lowermost end thereof and may be configured to attach the second chips 410 that are sequentially stacked. According to some example embodiments, the second adhesive layer 450 may include a film having adhesive properties on its own. For example, the second adhesive layer 450 may include a double-sided adhesive film. According to some example embodiments, the second adhesive layer 450 may include a tape-shaped material layer, a liquid coating curable material layer, or a combination thereof. Also, the second adhesive layer 450 may include a thermal setting structure, a thermal plastic, a UV cure material, or any combination thereof. The second adhesive layer 450 may be referred to as a DAF or an NCF.

As the second chip structure 400 is stacked in a stair type in the first direction, a portion of the upper surface of each of the second chips 410 may be exposed. That is, a portion of the upper surface of each of the second chips 410 may not be covered by the second chip 410 that is offset-stacked directly thereover. When the second chips 410 are stacked in the first direction, a portion of the upper surface of each of the second chips 410 in the second direction, e.g., a portion of the upper surface of each of the second chips 410 at an end of the second chips 410 corresponding to the second direction, which is opposite to and intersects the first direction, may be exposed upward.

The second chip pad 420 may be arranged on the upper surface of each of the second chips 410. According to some example embodiments, the second chip pad 420 may be arranged over an area where a portion of the upper surface of the second chip 410 is exposed upward. That is, the second chip pad 420 may be arranged at a second-direction end on the upper surface of the second chip 410. According to some example embodiments, the second chip pad 420 may be provided as a plurality of second chip pads 420, and the plurality of second chip pads 320 may be provided in an area exposed upward on the upper surface of each of the second chips 410. According to some example embodiments, the second chip pads 420 may be arranged in parallel in the second horizontal direction Y on the upper surface of the second chip 410.

The second wire 430 may be formed on one side of the second chip structure 400. According to some example embodiments, the second wire 430 may be formed on the side where the second chip pad 420 is arranged. That is, when the second chip structure 400 is stacked in the first direction, the second wire 430 may be arranged on the second-direction side that is opposite to and intersects the first direction. In other words, the second wire 430 may be arranged on the upper-surface side that is exposed upward from the second chip 410.

The second wire 430 may be provided as a plurality of second wires 430, and the plurality of second wires 430 may electrically connect the second chip pads 420 having different levels in the vertical direction Z. That is, the plurality of second wires 430 may connect adjacent second chips 410 to each other. Also, the plurality of second wires 430 may be arranged in the second horizontal direction Y to electrically connect the second chip pads 420 having different levels in the vertical direction Z. The second wire 430 may include gold, aluminum, or copper; however, the inventive concepts are not limited thereto.

The second chip 410 included in the second chip structure 400 may include a semiconductor chip. According to some example embodiments, the second chip 410 may include a memory chip. The memory chip may include, for example, a volatile memory chip such as DRAM or SRAM, or a nonvolatile memory chip such as PRAM, MRAM, FeRAM, or RRAM. Also, according to some example embodiments, the memory chip may include a wire bonding memory package or a high-bandwidth memory (HBM) package in which a plurality of memory chips are stacked in the vertical direction Z.

The controller chip 200 may be located on the upper surface of the package substrate 100. According to some example embodiments, the controller chip 200 may be located between the first chip structure 300 and the second chip structure 400. The controller chip 200 may be provided apart from the first chip 310 located at the lowermost end among the first chips 310 included in the first chip structure 300 by a certain distance in the first horizontal direction X. Also, the controller chip 200 may be provided apart from the second chip 410 located at the lowest end among the second chips 410 included in the second chip structure 400 by a certain distance in the first horizontal direction X. The controller chip 200 may include a chip that controls the first chips 310 and the second chips 410 included in the first chip structure 300 and the second chip structure 400. The controller chip 200 may include a processor chip such as an ASIC as a host such as CPU, GPU, or SoC. The controller chip 200 may include a logic chip including a logic circuit. According to some example embodiments, the logic chip may perform a function of transmitting a power signal, a ground signal, and a data signal to a memory chip.

The controller chip 200 may be mounted on the package substrate 100 in a flip-chip manner through a chip connection bump 210 such as a micro bump. According to some example embodiments, the underfill material layer 260 covering the chip connection bump 210 may be arranged between the controller chip 200 and the package substrate 100. The underfill material layer 260 may include, for example, an epoxy resin formed in a capillary underfill process.

As illustrated in FIG. 1, the underfill material layer 260 may have a tetragonal shape when viewed from above in the vertical direction Z. However, the shape of the underfill material layer 260 viewed from above in the vertical direction Z is not limited thereto, and the underfill material layer 260 may have a circular shape, a polygonal shape, and the like when viewed from above in the vertical direction.

According to some example embodiments, the side surface of the underfill material layer 260 may be perpendicular to the upper surface of the package substrate 100. According to some example embodiments, a horizontal distance D1 between the side surface of the underfill material layer 260 and the side surface of the controller chip 200 may be in a range of about 200 μm to about 400 μm. However, the horizontal distance D1 is not limited to the above range, and the horizontal distance D1 between the side surface of the underfill material layer 260 and the side surface of the controller chip 200 may be a reduced distance, for example the minimum distance, required for the controller chip 200 to be connected and fixed to the package substrate 100 through the chip connection bump 210 and the underfill material layer 260. According to some example embodiments, the center of the underfill material layer 260 along the X-Y plane may be substantially the same as the center of the controller chip 200 along the X-Y plane.

According to some example embodiments, a distance D2 from the side surface of the underfill material layer 260 to a structure closest thereto may be in a range of about 200 μm to about 600 μm. In this case, the structure may refer to any one of the first chip structure 300, the second chip structure 400, and the upper pad 110. The distance D2 from the side surface of the underfill material layer 260 to the closest structure to the side surface of the underfill material layer 260 may be understood as the distance by which the first chip structure 300, the second chip structure 400, and the upper pad 110 should be spaced apart from the underfill material layer 260 at a minimum or reduced distance.

For example, when the chips of the first chip structure 300 and the second chip structure 400 are offset-stacked in the first direction, the first chip structure 300 and the second chip structure 400 may be arranged as illustrated in FIG. 2. In this case, a structure closest to a side surface of the underfill material layer 260 that is closest to the first chip structure 300 among the side surfaces of the underfill material layer 260 may be the first chip structure 300 and may particularly be the first chip 310 located at the lowermost end in the first chip structure 300. Thus, the distance D2 from the side surface of the underfill material layer 260 to the closest structure may be understood as the distance from the −X-direction side surface (e.g., a side surface facing an inverse X direction) of the underfill material layer 260 to the X-direction side surface (e.g., a side surface facing the X direction) of the first chip 310 located at the lowermost end of the first chip structure 300. Also, a structure closest to a side surface of the underfill material layer 260 that is closest to the second chip structure 400 among the side surfaces of the underfill material layer 260 may be the upper pad 110. Thus, the distance D2 from the side surface of the underfill material layer 260 to the closest structure may be understood as the distance from the X-direction side surface of the underfill material layer 260 to the −X-direction side surface of the upper pad 110.

The first chip structure 300 and the second chip structure 400 may be arranged in various directions. Thus, the distance D2 from the side surface of the underfill material layer 260 to the closest structure to the side surface may be variously defined depending on the arrangement of the first chip structure 300 and the second chip structure 400. For example, when the first chips 310 of the first chip structure 300 are offset-stacked in the first direction and the second chips 410 of the second chip structure 400 are offset-stacked in the second direction, the second surface of the first chip structure 300 and the second surface of the second chip structure 400 may face each other. In this case, the distance D2 from the side surface of the underfill material layer 260 to the closest structure to the side surface may be understood as the distance from the −X-direction side surface of the underfill material layer 260 to the X-direction side surface of the first chip 310 (e.g., a second surface) located at the lowermost end of the first chip structure 300 and may also be understood as the distance from the X-direction side surface of the underfill material layer 260 to the −X-direction side surface (e.g., a second surface) of the second chip 410 located at the lowermost end of the second chip structure 400.

Also, when the first chips 310 of the first chip structure 300 are offset-stacked in the second direction and the second chips 410 of the second chip structure 400 are offset-stacked in the first direction, the first surface of the first chip structure 300 and the first surface of the second chip structure 400 may face each other. In this case, the distance D2 from the side surface of the underfill material layer 260 to the closest structure to the side surface may be understood as the distance from the −X-direction side surface of the underfill material layer 260 to the X-direction side surface of the upper pad 110 connected to the first chip structure 300 and may also be understood as the distance from the X-direction side surface of the underfill material layer 260 to the −X-direction side surface of the upper pad 110 connected to the second chip structure 400.

The molding member 600 may be configured to cover the first chip structure 300, the second chip structure 400, and the controller chip 200 on the upper surface of the package substrate 100. The molding member 600 may be formed from a thermosetting resin such as an epoxy resin, a thermoplastic resin such as a polyimide, or a resin including a reinforcement such as an inorganic filler particularly from Ajinomoto Build-up Film (ABF), FR-4, BT, or the like; however, the inventive concepts are not limited thereto and the molding member 600 may be formed from a molding material such as EMC or a photosensitive material such as a photoimageable encapsulant (PIE). In some example embodiments, a portion of the molding member 600 may be formed from an insulating material such as a silicon oxide layer, a silicon nitride layer, or a silicon oxynitride layer.

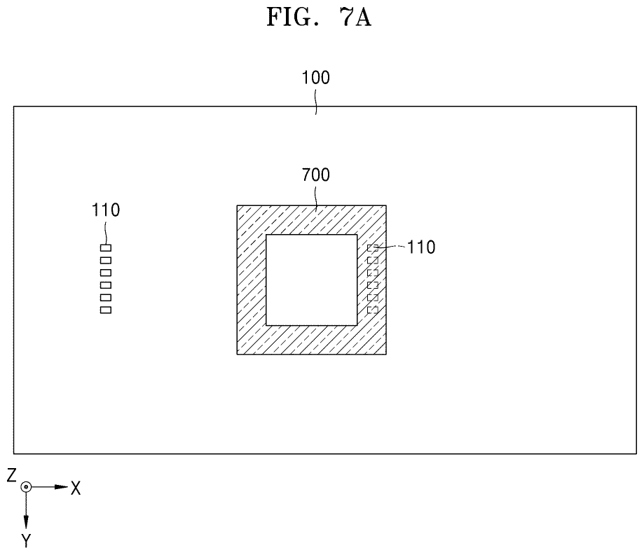

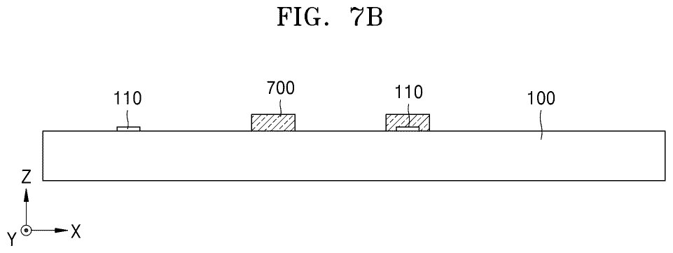

In the semiconductor package 10 according to the inventive concepts, the underfill material layer 260 may be formed with a reduced size, for example a minimum size, over the package substrate 100 without flowing down along the upper surface of the package substrate 100 through a masking tape 700 (see FIG. 7A) as described below. Thereafter, the masking tape 700 may be removed to form the first chip structure 300 and the second chip structure 400. Accordingly, the size of the semiconductor package 10 may be improved or optimized. It may be difficult to minimize or reduce the size of the underfill material layer 260 because the underfill material layer 260 flows along the upper surface of the package substrate 100. Also, when a protrusion is formed on the upper surface of the package substrate 100 to block the underfill material layer 260, there is a problem in that the size of the package substrate 100 increases by the area of the protrusion. However, in the semiconductor package 10 according to the inventive concepts, the size of the underfill material layer 260 may be optimized or reduced by preventing or reducing in likelihood the underfill material layer 260 from flowing along the upper surface of the package substrate, and the size of the semiconductor package 10 may also be minimized or reduced because a structure such as a protrusion may not be separately formed on the upper surface of the package substrate 100. Accordingly, the size of the semiconductor package 10 may be minimized or reduced.

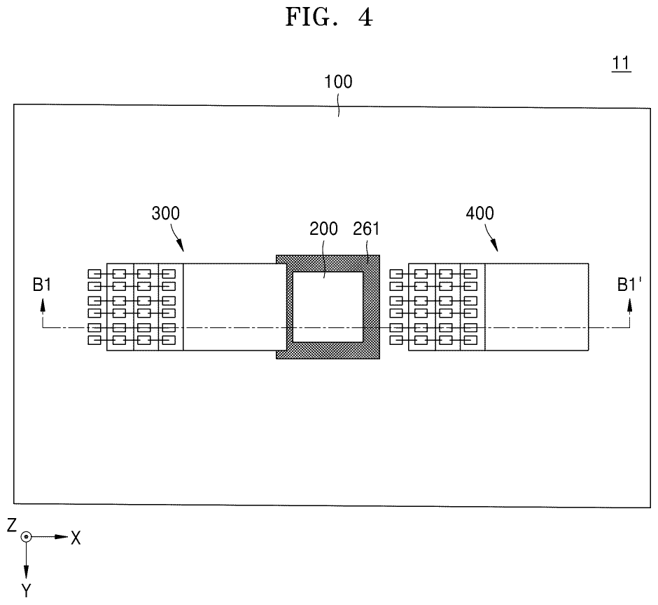

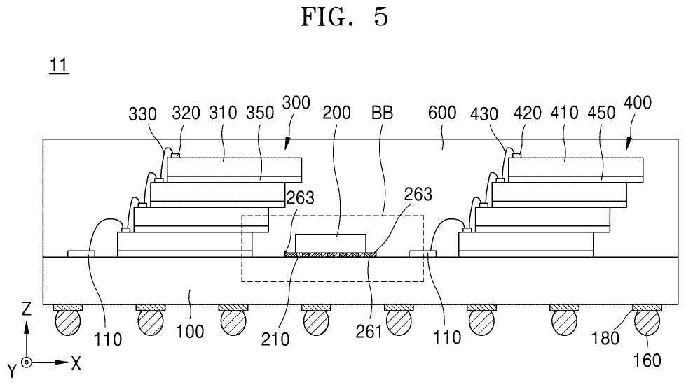

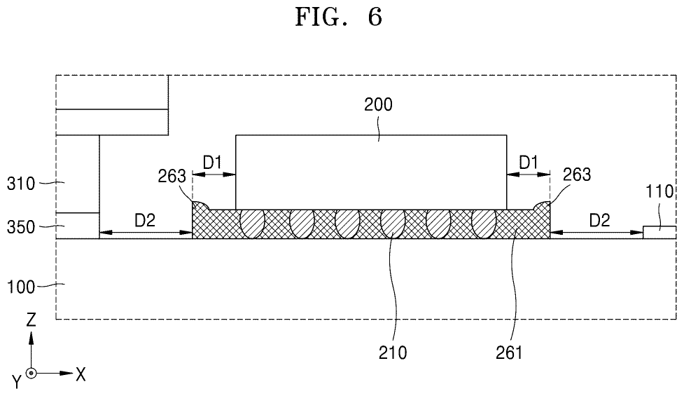

FIG. 4 is a plan view schematically illustrating a semiconductor package 11 according to embodiments. FIG. 5 is a cross-sectional view taken along line B1-B1′ of FIG. 4. FIG. 6 is an enlarged view of region BB of FIG. 5. Hereinafter, redundant descriptions between the semiconductor package 10 described above with reference to FIGS. 1 to 3 and the semiconductor package 11 of FIGS. 4 to 6 will be omitted and differences therebetween will be mainly described.

Referring to FIGS. 4 to 6, a semiconductor package 11 may include a package substrate 100, a controller chip 200, an underfill material layer 261, a first chip structure 300, a second chip structure 400, and a molding member 600. The package substrate 100 may be located under the controller chip 200, the first chip structure 300, and the second chip structure 400 and may be electrically connected to each of the controller chip 200, the first chip structure 300, and the second chip structure 400. The package substrate 100 may include an interconnection insulating layer and an interconnection pattern. An upper pad 110 may be located on the upper surface of the package substrate 100. The upper pad 110 may be provided as a plurality of upper pads 110 on the upper surface of the package substrate 100.

An external connection terminal 160 may be located on the lower surface of the package substrate 100 and may be electrically connected to the package substrate 100 through a lower pad 180 formed on the lower surface of the package substrate 100.

The first chip structure 300 may be arranged over the package substrate 100. The first chip structure 300 may include a first chip 310, a first adhesive layer 350, a first chip pad 320, and a first wire 330. The first chip structure 300 may have a structure in which a plurality of first chips 310 are offset-stacked in a first direction. According to some example embodiments, the first direction may be the same direction as the first horizontal direction X. According to some example embodiments, the plurality of first chips 310 may be offset-stacked in a direction −X intersecting a first horizontal direction X, or in a direction parallel to a second horizontal direction Y, or in a direction −Y intersecting the second horizontal direction Y.

The plurality of first chips 310 may be stacked over the package substrate 100 in a stack shape through the first adhesive layer 350. The first adhesive layer 350 may be located between the first chip 310 and the package substrate 100 and between the first chips 310.

As the first chip structure 300 is stacked in a stair type in the first direction, a portion of the upper surface of each of the first chips 310 may be exposed. That is, a portion of the upper surface of each of the first chips 310 may not be covered by the first chip 310 that is offset-stacked directly thereover. When the first chips 310 are stacked in the first direction, a portion of the upper surface of each of the first chips 310 in a second direction, which is opposite to and intersects the first direction, may be exposed upward.

The first chip pad 320 may be arranged on the upper surface of each of the first chips 310. According to embodiments, the first chip pad 320 may be arranged over an area where a portion of the upper surface of the first chip 310 is exposed upward. That is, the first chip pad 320 may be arranged at a second-direction end on the upper surface of the first chip 310.

The first wire 330 may be formed on one side of the first chip structure 300. According to some example embodiments, the first wire 330 may be formed on the side where the first chip pad 320 is arranged. That is, when the first chip structure 300 is stacked in the first direction, the first wire 330 may be arranged on the second-direction side that is opposite to and intersects the first direction.

The first chip 310 included in the first chip structure 300 may include a semiconductor chip. According to some example embodiments, the first chip 310 may include a memory chip.

The second chip structure 400 may be arranged over the package substrate 100 and apart from the first chip structure 300 in the horizontal direction (X or Y). The second chip structure 400 may include a second chip 410, a second adhesive layer 450, a second chip pad 420, and a second wire 430. The second chip structure 400 may have a structure in which a plurality of second chips 410 are offset-stacked in the first direction. In other words, the second chip structure 400 may have a structure in which a plurality of second chips 410 are stacked in a cascade type, that is, a stair type, in the first direction.

According to some example embodiments, the first chips 310 of the first chip structure 300 and the second chips 410 of the second chip structure 400 may be offset-stacked in the same direction. However, the inventive concepts are not limited thereto, and the first chips 310 of the first chip structure 300 and the second chips 410 of the second chip structure 400 may be offset-stacked in opposite directions.

The plurality of second chips 410 may be stacked over the package substrate 100 in a stack shape through the second adhesive layer 450. The second adhesive layer 450 may be located between the second chip 410 and the package substrate 100 and between the second chips 410.

As the second chip structure 400 is stacked in a stair type in the first direction, a portion of the upper surface of each of the second chips 410 may be exposed. That is, a portion of the upper surface of each of the second chips 410 may not be covered by the second chip 410 that is offset-stacked directly thereover. When the second chips 410 are stacked in the first direction, a portion of the upper surface of each of the second chips 410 in the second direction, which is opposite to and intersects the first direction, may be exposed upward.

The second chip pad 420 may be arranged on the upper surface of each of the second chips 410. According to some example embodiments, the second chip pad 420 may be arranged over an area where a portion of the upper surface of the second chip 410 is exposed upward. That is, the second chip pad 420 may be arranged at a second-direction end on the upper surface of the second chip 410.

The second wire 430 may be formed on one side of the second chip structure 400. According to some example embodiments, the second wire 430 may be formed on the side where the second chip pad 420 is arranged. That is, when the second chip structure 400 is stacked in the first direction, the second wire 430 may be arranged on the second-direction side that is opposite to and intersects the first direction.

The second chip 410 included in the second chip structure 400 may include a semiconductor chip. According to some example embodiments, the second chip 410 may include a memory chip.

The controller chip 200 may be located on the upper surface of the package substrate 100. According to some example embodiments, the controller chip 200 may be located between the first chip structure 300 and the second chip structure 400. The controller chip 200 may be provided apart from the first chip 310 located at the lowermost end among the first chips 310 included in the first chip structure 300 by a certain distance in the first horizontal direction X. Also, the controller chip 200 may be provided apart from the second chip 410 located at the lowest end among the second chips 410 included in the second chip structure 400 by a certain distance in the first horizontal direction X. The controller chip 200 may include a chip that controls the first chips 310 and the second chips 410 included in the first chip structure 300 and the second chip structure 400.

The controller chip 200 may be mounted on the package substrate 100 in a flip-chip manner through a chip connection bump 210 such as a micro bump. According to some example embodiments, the underfill material layer 261 covering the chip connection bump 210 may be arranged between the controller chip 200 and the package substrate 100.

As illustrated in FIG. 4, the underfill material layer 261 may have a tetragonal shape when viewed from above in the vertical direction Z. However, the shape of the underfill material layer 261 viewed from above in the vertical direction Z is not limited thereto, and the underfill material layer 261 may have a circular shape, a polygonal shape, and the like when viewed from above in the vertical direction.

According to some example embodiments, the side surface of the underfill material layer 261 may be perpendicular to the upper surface of the package substrate 100. According to some example embodiments, a horizontal distance D1 between the side surface of the underfill material layer 261 and the side surface of the controller chip 200 may be in a range of about 200 μm to about 400 μm. However, the horizontal distance D1 is not limited to the above range, and the horizontal distance D1 between the side surface of the underfill material layer 261 and the side surface of the controller chip 200 may be a reduced distance, for example the minimum distance, required for the controller chip 200 to be connected and fixed to the package substrate 100 through the chip connection bump 210 and the underfill material layer 261. According to some example embodiments, the center of the underfill material layer 261 along the X-Y plane may be substantially the same as the center of the controller chip 200 along the X-Y plane.

According to some example embodiments, a distance D2 from the side surface of the underfill material layer 261 to a structure closest to the side surface may be in a range of about 200 μm to about 600 μm. In this case, the structure may refer to any one of the first chip structure 300, the second chip structure 400, and the upper pad 110.

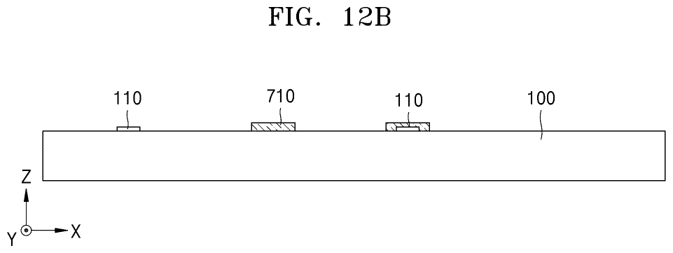

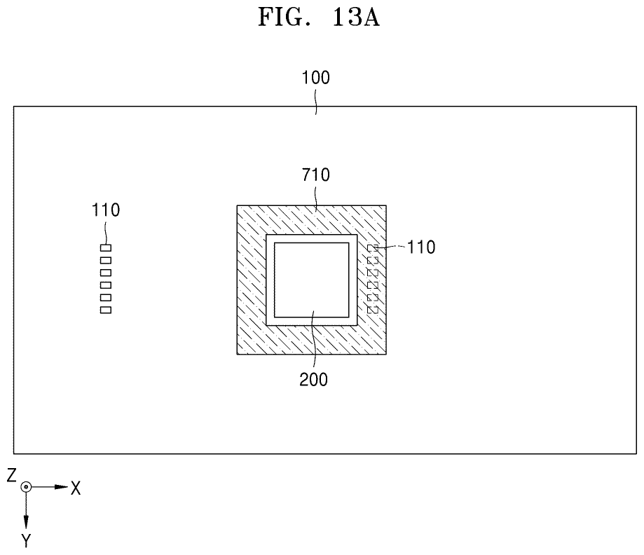

The underfill material layer 261 may include a protrusion 263. The protrusion 263 may have a shape that protrudes upward in the vertical direction on the upper surface of the underfill material layer 261. According to some example embodiments, the protrusion 263 may have an upwardly-convex shape. According to some example embodiments, the protrusion 263 may have a quadrant shape. The side surface of the protrusion 263 may be coplanar with the side surface of the underfill material layer 261, and the side surface of the protrusion 263 may be perpendicular to the package substrate 100. This may occur during a process of removing a masking tape 710 (see FIGS. 12A and 12B), which will be described in detail with reference to FIGS. 12A to 16B.

The molding member 600 may be configured to cover the first chip structure 300, the second chip structure 400, and the controller chip 200 on the upper surface of the package substrate 100.

Compared to the semiconductor package 10 described above with reference to FIGS. 1 to 3, in the semiconductor package 11 according to the inventive concepts, because a masking tape 710 (see FIGS. 12A and 12B) having a lower thickness in the vertical direction Z is used in the process of forming the underfill material layer 261, a portion of the underfill material layer 261 may flow along the upper surface of the masking tape 710. In this case, as the masking tape 710 is removed, the size of the underfill material layer 261 may be substantially the same as the size of the underfill material layer 260 of FIGS. 1 to 3, but in the underfill material layer 261 of the semiconductor package 11 of FIGS. 4 to 6, a protrusion 263 may be formed as a trace of the underfill material layer 261 flowing along the upper surface of the masking tape 710.

FIGS. 7A to 11B are cross-sectional views for describing a method of manufacturing the semiconductor package 10 of FIG. 1. Hereinafter, redundant descriptions with those given above with reference to FIGS. 1 to 3 will be omitted for conciseness.

First, referring to FIG. 7A and FIG. 7B, a masking tape 700 may be attached onto a package substrate 100 on which an upper pad 110 has been formed. The masking tape 700 may include a material that may be easily attached/removed to/from the package substrate 100. According to some example embodiments, the masking tape 700 may be understood as a general tape used in the process of manufacturing the semiconductor package 10.

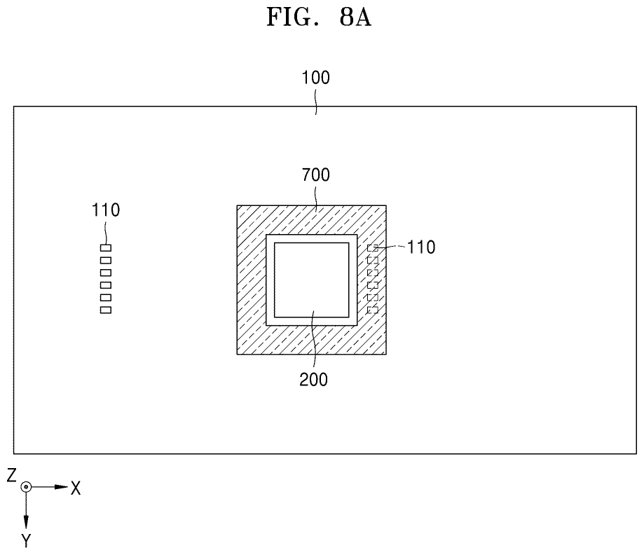

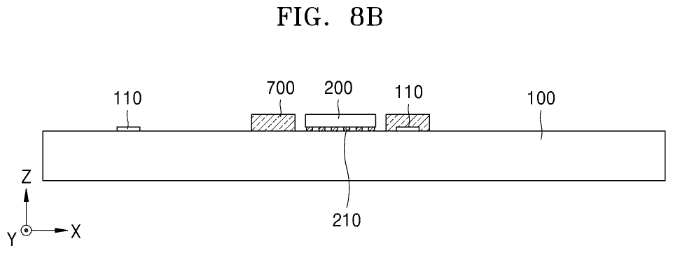

According to some example embodiments, the masking tape 700 may be formed to cover some of a plurality of upper pads 110 formed on the upper surface of the package substrate 100. According to some example embodiments, the masking tape 700 may be located to surround an area where a controller chip 200 (see FIGS. 8A and 8B) is to be mounted. The masking tape 700 may have a square ring shape when viewed from above in the vertical direction Z. In some example embodiments, the masking tape 700 may have a circular ring shape or a polygonal ring shape when viewed from above in the vertical direction Z.

Referring to FIG. 8A and FIG. 8B, a controller chip 200 may be mounted over an area surrounded by the masking tape 700 on the package substrate 100. The controller chip 200 may be electrically connected to the package substrate 100 through a chip connection bump 210.

The vertical level of the lower surface of the controller chip 200 may be located at a lower level than the vertical level of the upper surface of the masking tape 700. According to some example embodiments, the vertical level of the upper surface of the masking tape 700 may be substantially the same as the vertical level of the upper surface of the controller chip 200. According to some example embodiments, the vertical level of the upper surface of the masking tape 700 may be closer to the vertical level of the upper surface of the controller chip 200 than to the vertical level of the lower surface of the controller chip 200.

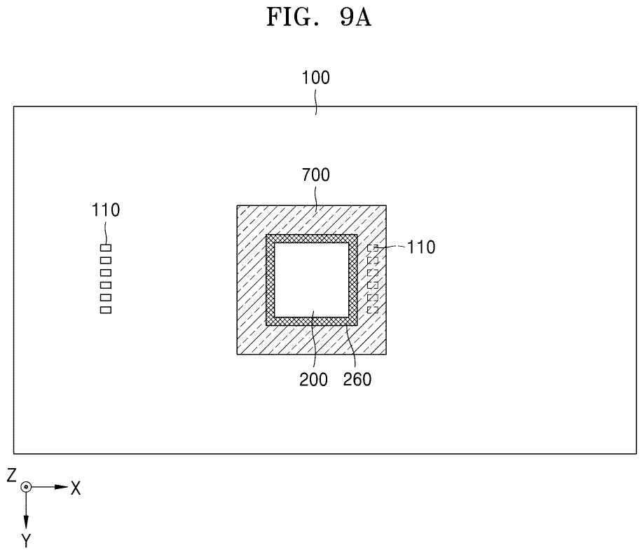

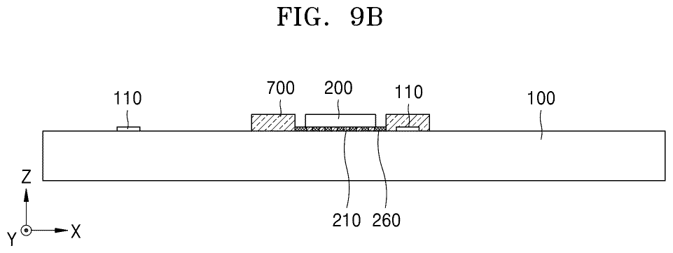

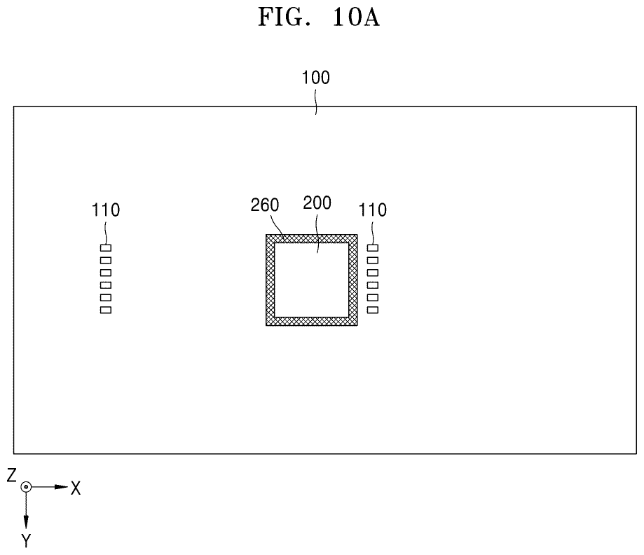

Referring to FIG. 9A and FIG. 9B, an underfill material layer 260 may be formed between the controller chip 200 and the package substrate 100. In this case, the underfill material layer 260 may be provided in a viscous state between the controller chip 200 and the package substrate 100. The underfill material layer 260 may cover the chip connection bump 210 between the controller chip 200 and the package substrate 100. The underfill material layer 260 may flow along the upper surface of the package substrate 100 due to viscosity. In this case, the flow of the underfill material layer 260 may be blocked or reduced in likelihood to flow by the masking tape 700. The underfill material layer 260 the flow of which is stopped by the masking tape 700 may be cured.

The cured underfill material layer 260 may be formed at a minimum or reduced size on the upper surface of the package substrate 100. Also, the shape of the underfill material layer 260 may be determined according to the shape of the masking tape 700. Ultimately, the shape and size of the underfill material layer 260 may be adjusted by adjusting the shape and size of the masking tape 700.

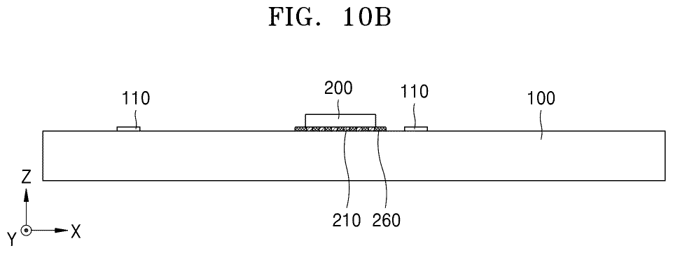

Referring to FIG. 10A and FIG. 10B, the masking tape 700 may be removed after the underfill material layer 260 is cured. As the masking tape 700 is removed, the loss of the area occupied by the masking tape 700 on the upper surface of the package substrate 100 may be removed. In other words, the space on the upper surface of the package substrate 100 may be more efficiently used by arranging another structure in the area previously occupied by the masking tape 700. Also, as the masking tape 700 is removed, the upper pad 110 sealed by the masking tape 700 may also be opened. The side surface of the underfill material layer 260 may be perpendicular to the package substrate 100. As the underfill material layer 260 is cured while the flow thereof is blocked or reduced in likelihood to flow by the masking tape 700, the side surface of the underfill material layer 260 may be perpendicular to the package substrate 100.

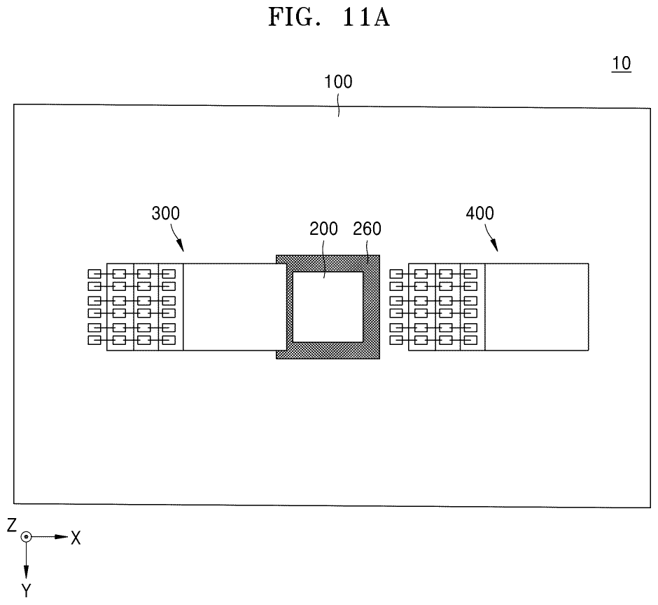

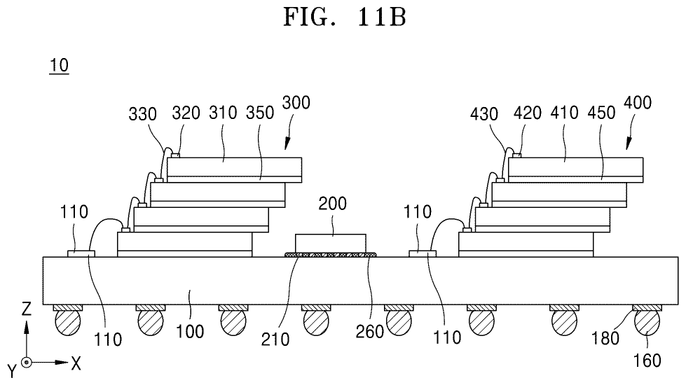

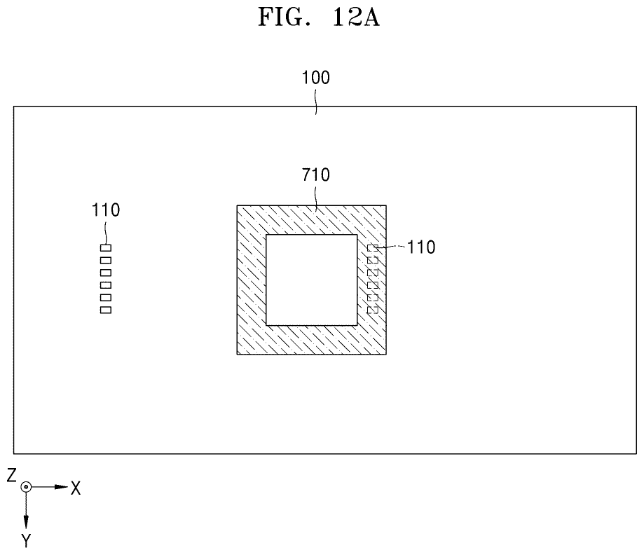

Referring to FIG. 11A and FIG. 11B, a first chip structure 300 and a second chip structure 400 may be formed, and a lower pad 180 and an external connection terminal 160 may be formed. The first chip structure 300 and the second chip structure 400 may be provided apart from each other in the horizontal direction (X or Y) with the controller chip 200 therebetween.

FIGS. 12A to 16B are cross-sectional views for describing a method of manufacturing the semiconductor package 11 of FIG. 2. Hereinafter, redundant descriptions with those given above with reference to FIGS. 4 to 6 will be omitted for conciseness.

First, referring to FIG. 12A and FIG. 12B, a masking tape 710 may be attached onto a package substrate 100 on which an upper pad 110 has been formed. The masking tape 710 may include a material that may be easily attached/removed to/from the package substrate 100. According to some example embodiments, the masking tape 710 may be understood as a general tape used in the process of manufacturing the semiconductor package 10.

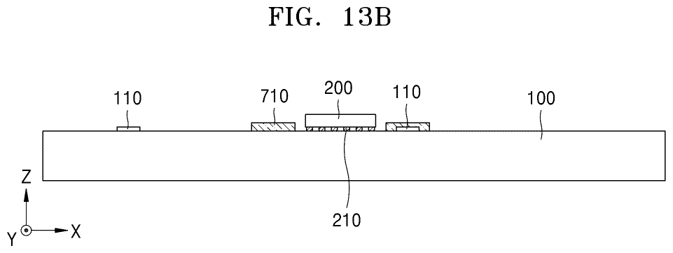

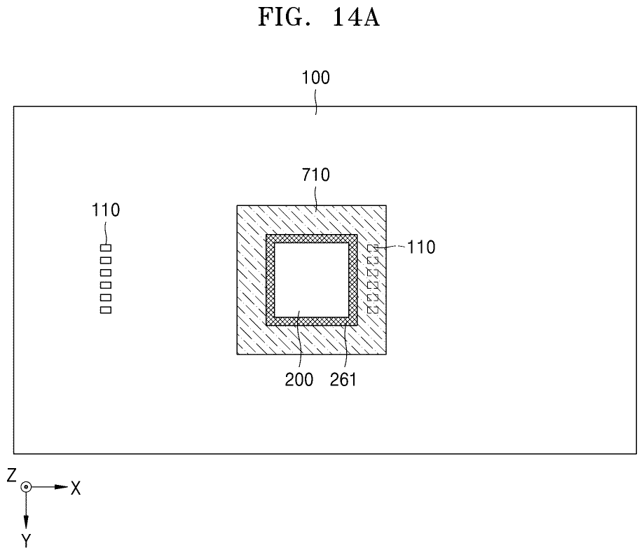

According to some example embodiments, the masking tape 710 may be formed to cover some of a plurality of upper pads 110 formed on the upper surface of the package substrate 100. According to some example embodiments, the masking tape 710 may be located to surround an area where a controller chip 200 (see FIGS. 13A and 13B) is to be mounted. The masking tape 710 may have a square ring shape when viewed from above in the vertical direction Z. In some example embodiments, the masking tape 710 may have a circular ring shape or a polygonal ring shape when viewed from above in the vertical direction Z.

Referring to FIG. 13A and FIG. 13B, a controller chip 200 may be mounted over an area surrounded by the masking tape 710 on the package substrate 100. The controller chip 200 may be electrically connected to the package substrate 100 through a chip connection bump 210.

According to some example embodiments, the vertical level of the upper surface of the masking tape 710 may be lower than the vertical level of the upper surface of the masking tape 700 described above with reference to FIGS. 7A to 11B. According to some example embodiments, the vertical level of the upper surface of the masking tape 710 may be substantially the same as the vertical level of the lower surface of the controller chip 200. According to some example embodiments, the vertical level of the upper surface of the masking tape 710 may be formed adjacent to the vertical level of the lower surface of the controller chip 200. The vertical level of the upper surface of the masking tape 710 may be closer to the vertical level of the lower surface than to the vertical level of the upper surface of the controller chip 200.

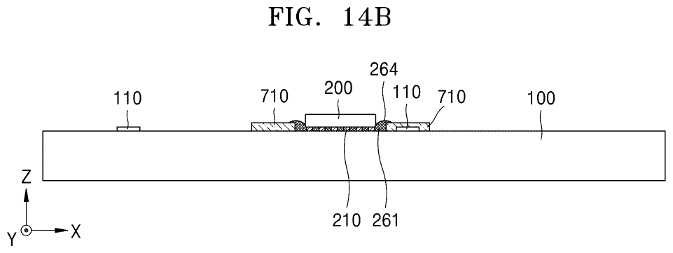

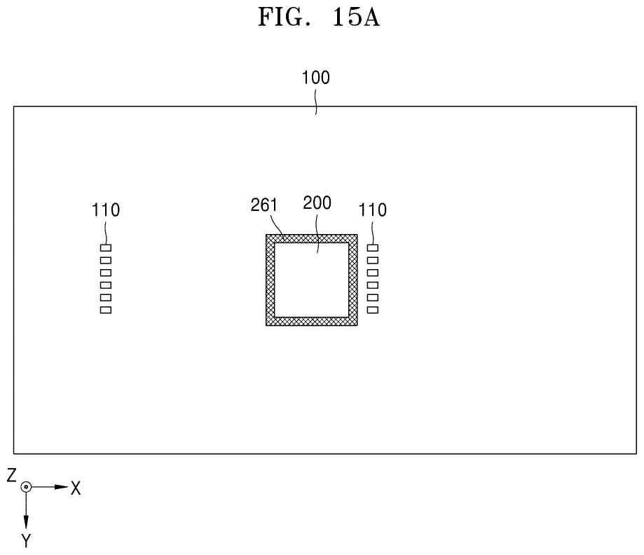

Referring to FIG. 14A and FIG. 14B, an underfill material layer 261 may be formed between the controller chip 200 and the package substrate 100. In this case, the underfill material layer 261 may be provided in a viscous state between the controller chip 200 and the package substrate 100. The underfill material layer 261 may cover the chip connection bump 210 between the controller chip 200 and the package substrate 100. The underfill material layer 261 may flow along the upper surface of the package substrate 100 due to viscosity. In this case, the flow of the underfill material layer 261 may be blocked or reduced in likelihood to flow by the masking tape 710. In this case, when the vertical level of the upper surface of the masking tape 710 is formed adjacent to the vertical level of the lower surface of the controller chip 200, a portion of the underfill material layer 261 may flow along the upper surface of the masking tape 710. A portion of the underfill material layer 261 may overflow along the upper surface of the masking tape 710. According to some example embodiments, a portion of the underfill material layer 261 flowing along the upper surface of the masking tape 710 may be understood as a protrusion 264. A cross-section of the protrusion 264 along the X-Z plane may have a semicircular shape. Thereafter, the underfill material layer 261 may be cured.

The cured underfill material layer 261 may be formed at a minimum or reduced area on the upper surface of the package substrate 100. Also, the shape of the underfill material layer 261 may be determined according to the shape of the masking tape 710. Ultimately, the shape and size of the underfill material layer 261 may be adjusted by adjusting the shape and size of the masking tape 710.

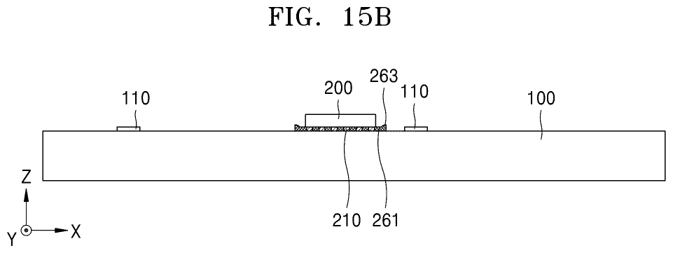

Referring to FIG. 15A and FIG. 15B, the masking tape 710 may be removed after the underfill material layer 261 is cured. The underfill material layer 261 cured after flowing along the upper surface of the masking tape 710 may be removed together during the process of removing the masking tape 710. The underfill material layer 261 may include a protrusion 263. After a portion of the underfill material layer 261 flows along the masking tape 710, as the underfill material layer 261 located on the upper surface of the masking tape 710 is removed, a protrusion 263 may be formed on the side surface of the underfill material layer 261. The protrusion 263 may have a quadrant shape. Alternatively, the protrusion 263 may have an upwardly-convex shape. The side surface of the underfill material layer 261 may be perpendicular to the package substrate 100.

As the masking tape 710 is removed, the loss of the area occupied by the masking tape 710 on the upper surface of the package substrate 100 may be removed. In other words, the space on the upper surface of the package substrate 100 may be more efficiently used by arranging another structure in the area previously occupied by the masking tape 710. Also, as the masking tape 710 is removed, the upper pad 110 sealed by the masking tape 710 may also be opened.

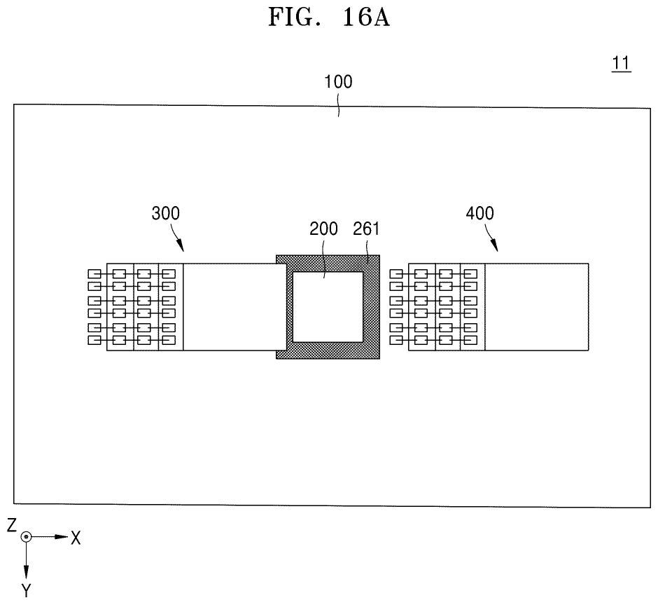

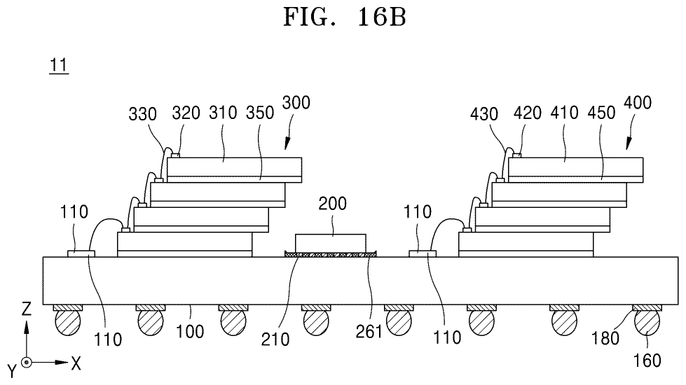

Referring to FIG. 16A and FIG. 16B, a first chip structure 300 and a second chip structure 400 may be formed, and a lower pad 180 and an external connection terminal 160 may be formed. The first chip structure 300 and the second chip structure 400 may be provided apart from each other in the horizontal direction (X or Y) with the controller chip 200 therebetween.

While the inventive concepts have been particularly shown and described with reference to some example embodiments thereof, it will be understood that various changes in form and details may be made therein without departing from the spirit and scope of the following claims.

What is claimed is:

1. A semiconductor package comprising:
a package substrate including an upper pad on an upper surface of the package substrate;
a first chip structure including a plurality of first chips offset-stacked in a first direction;
a controller chip on the package substrate and apart from the first chip structure in a horizontal direction;
a chip connection bump between the package substrate and the controller chip; and
an underfill material layer covering the chip connection bump,
wherein a side surface of the underfill material layer is perpendicular to the package substrate.

2. The semiconductor package of claim 1, further comprising:
a second chip structure on the package substrate and apart from the first chip structure in the horizontal direction with the controller chip between the second chip structure and the first chip structure,
wherein the second chip structure includes a plurality of second chips that are offset-stacked.

3. The semiconductor package of claim 2, wherein the plurality of first chips of the first chip structure and the second chips of the second chip structure are offset-stacked in a same direction.

4. The semiconductor package of claim 3, wherein a structure closest to the side surface of the underfill material layer is any one of the first chip structure, the second chip structure, or the upper pad.

5. The semiconductor package of claim 4, wherein a distance from the side surface of the underfill material layer to the structure closest to the side surface of the underfill material layer is in a range of 200 μm to 600 μm.

6. The semiconductor package of claim 1, wherein a protrusion is not on an area between the first chip structure and the controller chip, on the upper surface of the package substrate.

7. The semiconductor package of claim 1, wherein the underfill material layer has a tetragonal shape when viewed from above in a vertical direction.

8. The semiconductor package of claim 1, wherein a horizontal distance from the side surface of the underfill material layer to a side surface of the controller chip is in a range of 200 μm to 400 μm.

9. The semiconductor package of claim 1, further comprising:
a molding member covering the first chip structure and the controller chip, over the package substrate.

10. The semiconductor package of claim 1, wherein
the first chip structure includes four first chips, and
the first chips include memory chips.

11. A semiconductor package comprising:
a package substrate including an upper pad on an upper surface of the package substrate;
a first chip structure including a plurality of first chips offset-stacked in a first direction;
a controller chip on the package substrate and apart from the first chip structure in a horizontal direction;
a second chip structure on the package substrate and apart from the first chip structure in the horizontal direction with the controller chip between the first chip structure and the second chip structure, and the second chip structure including a plurality of second chips offset-stacked;
a chip connection bump between the package substrate and the controller chip; and
an underfill material layer configured to cover the chip connection bump,
wherein a side surface of the underfill material layer is perpendicular to the package substrate, and a protrusion protruding upward in a vertical direction is on an upper surface of the underfill material layer.

12. The semiconductor package of claim 11, wherein the plurality of first chips of the first chip structure and the plurality of second chips of the second chip structure are offset-stacked in a same direction.

13. The semiconductor package of claim 11, wherein the protrusion has a quadrant shape.

14. The semiconductor package of claim 11, wherein the underfill material layer has a tetragonal shape when viewed from above in the vertical direction.

15. The semiconductor package of claim 11, wherein a center of the underfill material layer along an X-Y plane is the same as a center of the controller chip along the X-Y plane.

16. A method of manufacturing a semiconductor package, the method comprising:
attaching a masking tape onto a package substrate including an upper pad so as to surround a certain area of the package substrate;
arranging a controller chip including a chip connection bump, in an area surrounded by the masking tape;
providing an underfill material layer having viscosity, between the controller chip and the package substrate;
curing the underfill material layer after flow of the underfill material layer is stopped by the masking tape;
removing the masking tape from an upper surface of the package substrate; and
mounting a first chip structure and a second chip structure on the upper surface of the package substrate so as to be spaced apart from the controller chip,
wherein the first chip structure includes a plurality of first chips that are offset-stacked, and the second chip structure includes a plurality of second chips that are offset-stacked.

17. The method of claim 16, wherein
a vertical level of an upper surface of the masking tape is closer to a vertical level of an upper surface of the controller chip than to a vertical level of a lower surface of the controller chip, and
in the providing of the underfill material layer having viscosity, between the controller chip and the package substrate, the underfill material layer does not flow along the upper surface of the masking tape.

18. The method of claim 16, wherein
a vertical level of an upper surface of the masking tape is closer to a vertical level of a lower surface of the controller chip than to a vertical level of an upper surface of the controller chip, and
in the providing of the underfill material layer having viscosity, between the controller chip and the package substrate, a portion of the underfill material layer flows along the upper surface of the masking tape.

19. The method of claim 18, wherein in the removing of the masking tape from the upper surface of the package substrate, a side surface of the underfill material layer is perpendicular to the package substrate, and a protrusion is formed on an upper surface of the underfill material layer.

20. The method of claim 19, wherein the protrusion has a quadrant shape.
